(19) United States
(12) Patent Application Publication
(10) Pub. No.: US 2024/0355860 A1
(43) Pub. Date: Oct. 24, 2024

(54) ETCH BLOCK STRUCTURE FOR DEEP TRENCH ISOLATION RECESS CONTAINMENT

(71) Applicant: Taiwan Semiconductor Manufacturing Company, Ltd., Hsinchu (TW)

(72) Inventors: Hsin-Hung Chen, Tainan City (TW); Wen-I Hsu, Tainan City (TW); Wei Long Chen, New Taipei City (TW); Ming-En Chen, Tainan City (TW); Feng-Chi Hung, Chu-Bei City (TW); Jen-Cheng Liu, Hsin-Chu City (TW); Dun-Nian Yaung, Taipei City (TW)

(21) Appl. No.: 18/346,568

(22) Filed: Jul. 3, 2023

Related U.S. Application Data
(60) Provisional application No. 63/497,769, filed on Apr. 24, 2023.

(51) Int. Cl. H01L 27/146

(52) U.S. Cl. CPC H01L 27/14636; H01L 27/1463; H01L 27/14685

(57) ABSTRACT

The present disclosure, in some embodiments, relates to an image sensor integrated chip. The image sensor integrated chip includes a plurality of gate structures arranged along a first side of a substrate within a plurality of pixel regions. An etch block structure is arranged on the first side of the substrate between neighboring ones of the plurality of gate structures. A contact etch stop layer (CESL) is arranged on the etch block structure between the neighboring ones of the plurality of gate structures. An isolation structure is disposed between one or more sidewalls of the substrate and extends from a second side of the substrate to the first side of the substrate. The etch block structure is vertically between the isolation structure and the CESL.

### REFERENCE TO RELATED APPLICATION

This application claims the benefit of U.S. Provisional Application No. 63/497,769, filed on Apr. 24, 2023, the contents of which are hereby incorporated by reference in their entirety.

### BACKGROUND

Integrated circuits (IC) with image sensors are used in a wide range of modern-day electronic devices, such as cameras and cell phones, for example. In recent years, complementary metal-oxide semiconductor (CMOS) image sensors have begun to see widespread use, largely replacing charge-coupled device (CCD) image sensors. Compared to CCD image sensors, CMOS image sensors are increasingly favored due to low power consumption, a small size, fast data processing, a direct output of data, and low manufacturing cost.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of some embodiments of an integrated chip comprising an etch block structure configured to mitigate damage due to over-etching during formation of a back-side isolation structure.

FIGS. 2A-2B illustrate some additional embodiments of an image sensor integrated chip (IC) comprising a disclosed etch block structure.

FIG. 3 illustrates a cross-sectional view of some additional embodiments of an image sensor IC comprising a disclosed etch block structure.

FIGS. 4A-4C illustrate some additional embodiments of an image sensor IC comprising a disclosed etch block structure.

FIG. 5 illustrates a top-view of some additional embodiments of an image sensor IC comprising a disclosed etch block structure.

FIGS. 6A-6B illustrate some additional embodiments of an image sensor IC comprising a disclosed etch block structure.

FIGS. 7A-7D illustrate some additional embodiments of an image sensor IC comprising a disclosed etch block structure.

FIG. 8 illustrates a cross-sectional view of some additional embodiments of an image sensor IC comprising a disclosed etch block structure.

FIG. 9 illustrates a cross-sectional view of some additional embodiments of an image sensor IC comprising a disclosed etch block structure.

FIG. 10 illustrates a cross-sectional view of some additional embodiments of an image sensor IC comprising a disclosed etch block structure.

FIG. 11 illustrates some embodiments of a multi-dimensional integrated chip structure comprising an image sensor IC including a disclosed etch block structure.

FIGS. 12-29 illustrate cross-sectional views of some embodiments of a method of forming an image sensor IC comprising a disclosed etch block structure.

FIG. 30 illustrates a flow diagram of some embodiments of a method of forming an image sensor IC comprising a disclosed etch block structure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

CMOS image sensors (CIS) typically comprise a plurality of pixel regions arranged in an array. The plurality of pixel regions respectively include an image sensing element arranged within a semiconductor substrate. The image sensing elements are laterally surrounded by one or more isolation structures that are configured to electrically isolate adjacent pixel regions from one another. A plurality of micro-lenses are disposed over the plurality of pixel regions. The plurality of micro-lenses are respectively configured to focus incident radiation (e.g., incident light) onto an underlying image sensing element. Upon receiving the incident radiation, the image sensing element is configured to convert the incident radiation to an electric signal. The electric signal from the image sensing element can be processed by a signal processing unit to determine an image captured by the CIS.

As the size of components within integrated chips have decreased (i.e., scaled), the sizes of pixel regions within the integrated chips have also decreased thereby making electrical isolation between adjacent pixel regions more difficult. The use of back-side isolation structures (e.g., back-side deep trench isolation (BDTI) structures) between adjacent pixel regions is preferrable to implant isolation as it provides for better electrical isolation. Back-side isolation structures are normally formed by etching a trench into a back-side of a substrate and subsequently filling the trench with one or more dielectric materials. In some examples, the substrate may be etched until the trench reaches a shallow trench isolation (STI) structure arranged along a front-side of the substrate.

However, STI structures typically have a greater width than back-side isolation structures and may impinge upon an active area of an adjacent image sensing element. Because the formation of STI structures along the front-side of the substrate may damage the substrate, the formation of the STI structures can result in defects that negatively impact an image sensing element (e.g., leading to leakage paths between adjacent pixel regions, increased dark current, white pixels, reduced full well capacity (FWC), etc.). Furthermore, due to materials typically used in an STI structure, etching into the STI structure to form the back-side isolation structure may result in over-etching of the STI structure that can further degrade performance of a pixel region. Due to etch loading, the over-etching may be more pronounced at cross-roads between back-side isolation structure segments extending in different directions (e.g., perpendicular directions).

In some embodiments, the present disclosure relates to an image sensor integrated chip (IC) comprising an etch block structure configured to mitigate damage due to over-etching during formation of a back-side isolation structure. The image sensor IC comprises a plurality of gate structures arranged along a first side of a substrate within a plurality of pixel regions. An etch block structure is arranged on the first side of the substrate between neighboring ones of the plurality of gate structures, and a contact etch stop layer is arranged on the etch block structure. A back-side isolation structure extends between one or more sidewalls of the substrate from a second side of the substrate to the first side of the substrate. The back-side isolation structure terminates into the etch block structure. By terminating the back-side isolation structure into the etch block structure, the etch block structure is able to mitigate over-etching during formation of the back-side isolation structure. Furthermore, because the etch block structure is arranged on the first side of the substrate, it can be formed without etching the substrate thereby preventing damage (e.g., defects) to the substrate that can negatively impact the image sensor IC (e.g., that can lead to increased dark current, white pixels, and/or reduced FWC, etc.).

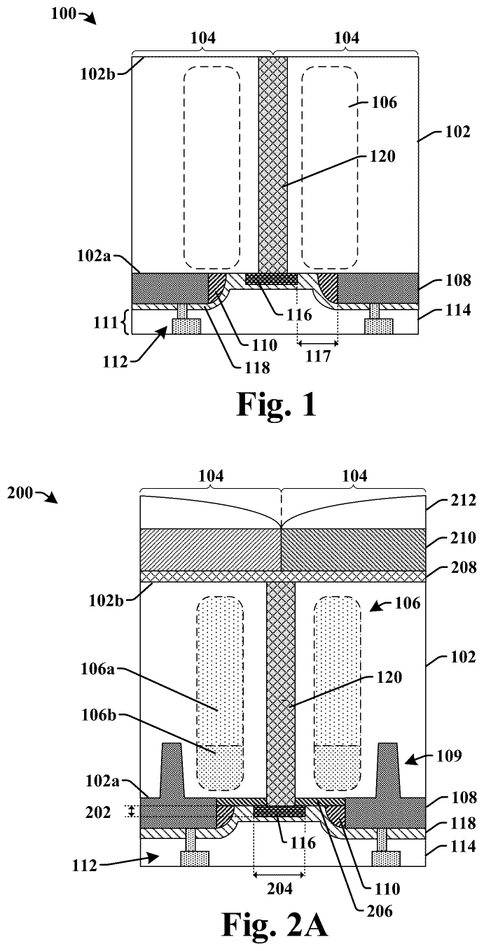

FIG. 1 illustrates a cross-sectional view of some embodiments of an image sensor integrated chip (IC) 100 comprising an etch block structure configured to mitigate damage due to over-etching during formation of a back-side isolation structure.

The image sensor IC 100 comprises a substrate 102 having a first side 102a (e.g., a front-side) and a second side 102b (e.g., a back-side) opposing the first side 102a. Image sensing elements 106 are respectively disposed within a plurality of pixel regions 104 of the substrate 102. The image sensing elements 106 are configured to convert incident radiation to an electrical signal. A plurality of gate structures 108 are arranged along the first side 102a of the substrate 102 within the plurality of pixel regions 104. In some embodiments, one or more sidewall spacers 110 may be disposed along opposing sides of respective ones of the plurality of gate structures 108. An interconnect structure 111 is arranged on the first side 102a of the substrate 102. In some embodiments, the interconnect structure 111 comprises a plurality of conductive interconnects 112 disposed within an inter-level dielectric (ILD) structure 114 and coupled to the plurality of gate structures 108.

An etch block structure 116 is arranged on the first side 102a of the substrate 102 between first and second pixel regions of the plurality of pixel regions 104. The etch block structure 116 has outermost sidewalls that are laterally between neighboring ones of the plurality of gate structures 108, as viewed in the cross-sectional view. In some embodiments, the outermost sidewalls of the etch block structure 116 may be laterally separated from neighboring ones of the plurality of gate structures 108 by non-zero distances 117. In some embodiments, a substantially flat surface of the substrate 102 may continuously extend from directly below one of the plurality of gate structures 108 to directly below a bottom of the etch block structure 116 that faces the substrate 102.

A contact etch stop layer (CESL) 118 is disposed on the etch block structure 116 and the plurality of gate structures 108. The CESL 118 laterally extends past the outermost sidewalls of the etch block structure 116. In some embodiments, the CESL 118 extends along an upper surface and along the outermost sidewalls of the etch block structure 116. In such embodiments, the CESL 118 is laterally between the etch block structure 116 and the one or more sidewall spacers 110 surrounding neighboring ones of the plurality of gate structures 108.

A back-side isolation structure 120 extends through the substrate 102 between neighboring ones of the plurality of pixel regions 104. In some embodiments, the back-side isolation structure 120 may comprise one or more dielectric materials arranged within a trench that is formed by one or more sidewalls of the substrate 102. The back-side isolation structure 120 extends from the second side 102b of the substrate 102 to the etch block structure 116. The back-side isolation structure 120 vertically abuts the etch block structure 116, so that the etch block structure 116 vertically separates the back-side isolation structure 120 from the CESL 118. Because the back-side isolation structure 120 vertically abuts the etch block structure 116, the etch block structure 116 is configured to stop an etching process used to form the back-side isolation structure 120. By using the etch block structure 116 to stop the etching process used to form the back-side isolation structure 120, damage to the substrate 102, the CESL 118, and/or ILD structure 114 can be prevented thereby improving a reliability and performance (e.g., decreasing dark current and/or white pixels, increasing full well capacity (FWC), etc.) associated with the image sensing elements 106 within the image sensor IC 100.

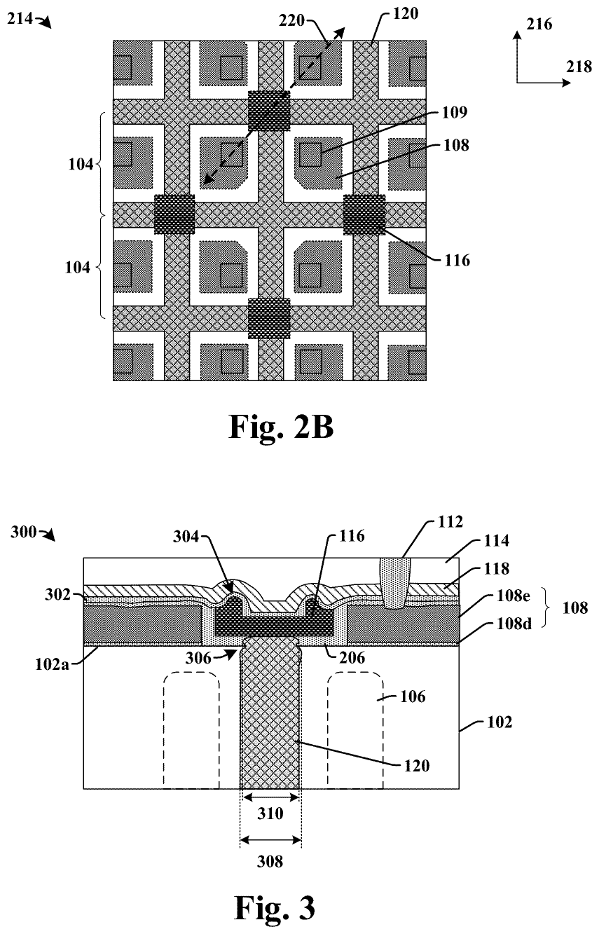

FIG. 2A illustrates a cross-sectional view of some additional embodiments of an image sensor integrated chip (IC) 200 comprising a disclosed etch block structure.

The image sensor IC 200 comprises a plurality of image sensing elements 106 respectively disposed within a plurality of pixel regions 104 of the substrate 102. In various embodiments, the substrate 102 may be any type of semiconductor body (e.g., silicon, silicon-germanium, SOI, etc.), as well as any other type of semiconductor and/or epitaxial layers, associated therewith. In various embodiments, the plurality of image sensing elements 106 may comprise a photodiode, a phototransistor, or the like. In some embodiments, the plurality of image sensing elements 106 may comprise a photodiode having a first doped region 106a having a first doping type (e.g., comprising p-type dopants) and a second doped region 106b having a second doping type (e.g., comprising n-type dopants).

A plurality of gate structures 108 are arranged along a first side 102a of the substrate 102. In some embodiments, the plurality of gate structures 108 may correspond to one or more of a transfer transistor, a source-follower transistor, a row select transistor, and/or a reset transistor. In some embodiments, the plurality of gate structures 108 may comprise vertical transfer gates. In such embodiments, the plurality of gate structures 108 may respectively comprise a protrusion 109 extending outward from a surface of a gate structure facing the substrate 102 to within the substrate 102. In some embodiments, one or more sidewall spacers 110 may be disposed along opposing sides of respective ones of the plurality of gate structures 108.

In some embodiments, the plurality of gate structures 108 are coupled to a plurality of conductive interconnects 112 disposed within an inter-level dielectric (ILD) structure 114 arranged on the first side 102a of the substrate 102. In some embodiments, the plurality of conductive interconnects 112 comprise conductive contacts, interconnect wires, and/or interconnect vias disposed within a plurality of stacked inter-level dielectric (ILD) layers of the ILD structure 114. In some embodiments, the plurality of conductive interconnects 112 may comprise tungsten, copper, aluminum, or the like. In various embodiments, the plurality of stacked ILD layers may comprise one or more of silicon dioxide, doped silicon dioxide (e.g., carbon doped silicon dioxide), silicon oxynitride, borosilicate glass (BSG), phosphoric silicate glass (PSG), borophosphosilicate glass (BPSG), fluorinated silicate glass (FSG), or the like.

An etch block structure 116 is arranged along the first side 102a of the substrate 102. In some embodiments, the etch block structure 116 may be separated from the substrate 102 by a first dielectric 206. In some embodiments, the etch block structure 116 may comprise a nitride-based layer, such as silicon nitride, silicon oxynitride, or the like. In other embodiments, the etch block structure 116 may comprise a carbide-based layer (e.g., silicon carbide, silicon oxycarbide), a titanium nitride-based layer, an aluminum-based layer, or the like. In some embodiments, the etch block structure 116 may comprise and/or be a same material as the one or more sidewall spacers 110. In some embodiments, the etch block structure 116 may have a thickness 202 that is in a range of between approximately 5 nanometers (nm) and approximately 100 nm, between approximately 20 nm and approximately 100 nm, between approximately 30 nm and approximately 60 nm, or other similar values.

A contact etch stop layer (CESL) 118 is disposed on the etch block structure 116 and the plurality of gate structures 108. In some embodiments, the CESL 118 separates the plurality of gate structures 108 from a closest one of the plurality of stacked ILD layers within the ILD structure 114. The CESL 118 laterally extends past the outermost sidewalls of the etch block structure 116. In some embodiments, the CESL 118 may comprise silicon carbide, silicon nitride, titanium nitride, tantalum nitride, or the like.

A back-side isolation structure 120 is arranged within the substrate 102 between neighboring ones of the plurality of pixel regions 104. In some embodiments, the back-side isolation structure 120 may comprise one or more dielectric materials arranged within a trench that is formed by one or more sidewalls of the substrate 102. The back-side isolation structure 120 extends from the second side 102b of the substrate 102 to the etch block structure 116. The etch block structure 116 laterally extends past one or more sidewalls of the back-side isolation structure 120. In some embodiments, the etch block structure 116 may have a width 204 that is greater than a width of the back-side isolation structure 120. In some embodiments, the width 204 may be in a range of between approximately 50 nm and approximately 20,000 nm, between approximately 100 nm and approximately 15,000 nm, or other similar values. In some embodiments, the width 204 of the etch block structure 116 may be larger than the width of the back-side isolation structure 120 by a value having a range of between at least approximately 30 nm to approximately 10,000 nm.

A plurality of color filters 210 are disposed on a second side 102b of the substrate 102 opposing the first side 102a. A plurality of micro-lenses 212 are arranged on the plurality of color filters 210. The plurality of micro-lenses 212 respectively have a curved surface facing away from the substrate 102. The curved surface is configured to focus incident radiation towards an underlying one of the image sensing elements 106.

FIG. 2B illustrates a top-view 214 of some additional embodiments of an image sensor IC comprising a disclosed etch block structure. FIG. 2A is taken along cross-sectional line 220 of top-view 214.

As shown in top-view 214, the plurality of pixel regions 104 are arranged within the substrate 102 in an array having columns and rows. The columns extend in a first direction 216 and the rows extend in a second direction 218 that is perpendicular to the first direction 216. In some embodiments, the plurality of pixel regions 104 may be arranged at a pitch that is in a range of between approximately 200 nm and approximately 2,000 nm, between approximately 250 nm and approximately 500 nm, approximately 400 nm, or other similar values. The back-side isolation structure 120 wraps around respective ones of the plurality of pixel regions 104 in a closed loop, so as to separate neighboring ones of the plurality of pixel regions 104 from one another.

The back-side isolation structure 120 comprises a grid layout that extends in the first direction 216 and in the second direction 218, as viewed in the top-view 214. The etch block structure 116 is arranged below cross-roads (e.g., intersections) between segments of the back-side isolation structure 120 extending in the first direction 216 and the second direction 218. For example, the etch block structure 116 is arranged on the first side of the substrate below an intersection of a first segment extending in the first direction 216 and a second segment extending in the second direction 218. Due to etch-loading, an etching process that is used to form the back-side isolation structure 120 within the substrate 102 will have a higher etching rate at the cross-roads than in other areas. The higher etching rate will lead to increased over-etching and potential damage to the substrate and/or ILD structure. By locating the etch block structure 116 below the cross-roads, the etch block structure 116 is able to mitigate over-etching caused by etch-loading (e.g., and therefore improve a performance and/or reliability of the image sensor IC) without impacting a design of and/or fabrication process used to make the disclosed image sensor IC.

FIG. 3 illustrates a cross-sectional view of some additional embodiments of an image sensor IC 300 comprising a disclosed etch block structure.

The image sensor IC 300 comprises an etch block structure 116 disposed on a first side 102a (e.g., a front-side) of a substrate 102 between neighboring ones of a plurality of gate structures 108. The plurality of gate structures 108 respectively comprise a gate dielectric 108d (e.g., comprising an oxide, a nitride, etc.) and a gate electrode 108c (e.g., comprising polysilicon, metal, and/or the like). The gate dielectric 108d separates the gate electrode 108e from the substrate 102.

The etch block structure 116 is separated from the substrate 102 by a first dielectric 206. The first dielectric 206 may extend to outermost sidewalls of neighboring ones of the plurality of gate structures 108. In some embodiments, the first dielectric 206 further extends along one or more sidewalls of the etch block structure 116. In some embodiments, a second dielectric 302 is arranged over the first dielectric 206, the etch block structure 116, and the plurality of gate structures 108. A contact etch stop layer (CESL) 118 is arranged on the second dielectric 302. In some embodiments, the CESL 118 may be laterally separated from one or more sidewalls of the etch block structure 116 by the second dielectric 302.

In some embodiments, the etch block structure 116 comprises a height that varies over a width of the etch block structure 116. In some embodiments, the etch block structure 116 may comprise one or more protrusions 304 arranged on opposing sides of the etch block structure 116, as viewed in a cross-sectional view. The one or more protrusions 304 extend outward from an upper surface of the etch block structure 116, which is coupled to an outermost sidewall of the etch block structure 116. In some embodiments, the etch block structure 116 has a smaller thickness at a lateral center of the etch block structure 116 than between the lateral center and an outermost sidewall of the etch block structure 116.

A back-side isolation structure 120 vertically extends through the substrate 102 and the first dielectric 206 to contact the etch block structure 116. A side of back-side isolation structure 120 may comprise a divot 306 along an interface between the substrate 102 and the first dielectric 206. Within the first dielectric 206, the back-side isolation structure 120 has a bulbous segment that protrudes laterally outward from the divot 306. The bulbous segment has a curved outermost sidewall that is surrounded by the first dielectric 206. In some embodiments, the back-side isolation structure 120 has a first width 308 directly between sidewalls of the substrate 102 and a second width 310 directly between sidewalls of the first dielectric 206. The first width 308 is different than the second width 310. In some embodiments, the first width 308 may be larger than the second width 310.

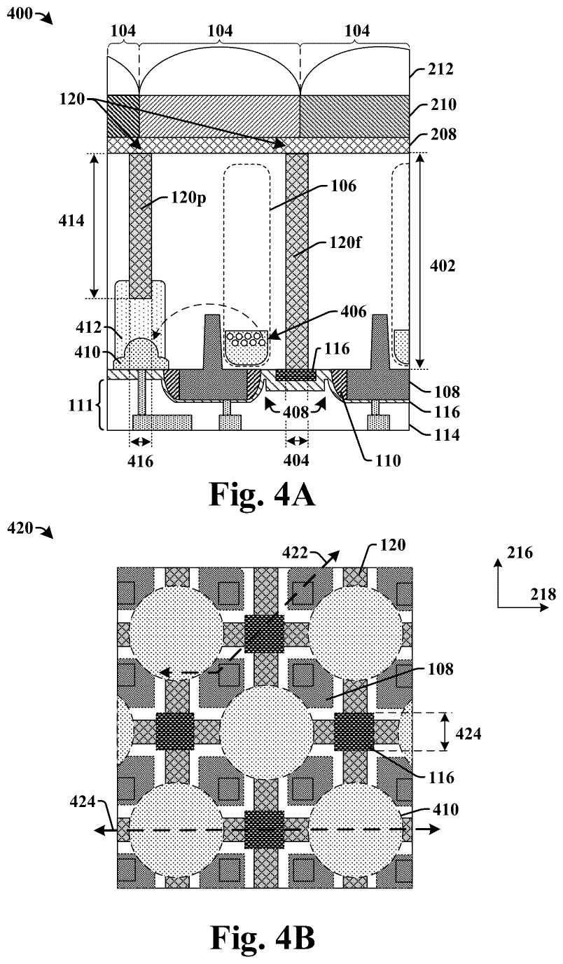

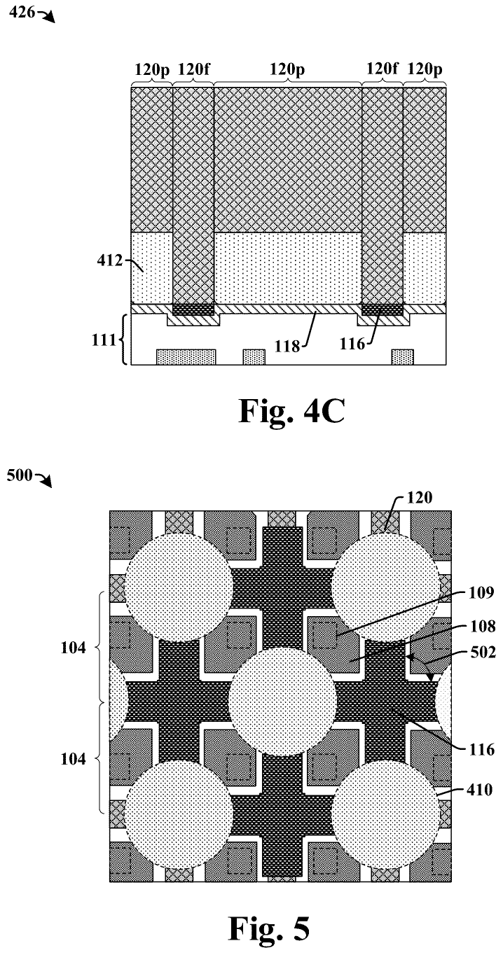

FIG. 4A illustrates a cross-sectional view of some additional embodiments of an image sensor IC 400 comprising a disclosed etch block structure.

The image sensor IC 400 comprises a substrate 102 having a plurality of pixel regions 104 respectively comprising one of a plurality of gate structures 108. An etch block structure 116 is disposed on the substrate 102 between neighboring ones of the plurality of gate structures 108, as viewed in the cross-sectional view. A back-side isolation structure 120 extends through the substrate 102 along opposing sides of the plurality of pixel regions 104. The back-side isolation structure 120 may comprise one or more full isolation structure segments 120f and one or more partial isolation structure segments 120p. The one or more full isolation structure segments 120f have a first height 402 and a first width 404. The one or more partial isolation structure segments 120p have a second height 414 and a second width 416. The first height 402 is larger than the second height 414.

In some embodiments, the first height 402 is in a range of between approximately 1 micron (μm) and approximately 20 μm, between approximately 2 μm and approximately 15 μm, approximately 3 μm, or other similar values. In some embodiments, the first height 402 may be greater than or equal to a thickness of the substrate 102. In some embodiments, the first width 404 is in a range of between approximately 10 nm and approximately 10000 nm, between approximately 20 μm and approximately 9990 μm, or other similar values. In some embodiments, the second height 414 is in a range of between approximately 1 μm and approximately 15 μm, between approximately 2 μm and approximately 14 μm, or other similar values. In some embodiments, the second width 416 is in a range of between approximately 10 nm and approximately 10000 nm, between approximately 20 μm and approximately 9990 μm, or other similar values.

In some embodiments, a floating diffusion region 410 is arranged within the substrate 102 below the one or more partial isolation structure segments 120p. In such embodiments, the floating diffusion region 410 may be shared between neighboring ones of the plurality of pixel regions 104, thereby increasing an area that may be used for the plurality of image sensing elements 106 and improving a full well capacity of the plurality of image sensing elements 106. The floating diffusion region 410 is a doped region of the substrate 102. In some embodiments, the plurality of gate structures 108 may comprise transfer gates configured to selectively control the movement charge carriers 406 from the plurality of image sensing elements 106 to the floating diffusion region 410. In some embodiments, a doped isolation region 412 (e.g., a doped well region) may be arranged within the substrate 102 between the one or more partial isolation structure segments 120p and the floating diffusion region 410.

An etch block structure 116 is disposed vertically below the one or more full isolation structure segments 120f and laterally outside of the one or more partial isolation structure segments 120p. An interconnect structure 111 is separated from the etch block structure 116 and the plurality of gate structures 108 by a CESL 118. In some embodiments, the CESL 118 may comprise one or more pits 408 arranged on opposing sides of the etch block structure 116. The one or more pits 408 are formed by opposing sidewalls of the CESL 118. The interconnect structure 111 comprises a plurality of conductive interconnects 112 arranged within an ILD structure 114. In some embodiments, the plurality of conductive interconnects 112 comprise one or more conductive contacts that extend through the CESL 118 to below a top of the etch block structure 116 facing away from the substrate 102.

FIG. 4B illustrates a top-view 420 of some embodiments of the image sensor IC 400 of FIG. 4A. FIG. 4A is taken along cross-sectional line 422 of top-view 420. As shown in top-view 420, the etch block structure 116 is arranged at cross-roads between vertically and horizontally extending segments of the back-side isolation structure 120. FIG. 4C illustrates a cross-sectional view 426 of some embodiments of the image sensor IC of FIG. 4B taken along cross-sectional line 424. As shown in cross-sectional view 426, above the etch block structure 116 the back-side isolation structure 120 comprises one or more full isolation structure segments 120f. Outside of the etch block structure 116, the back-side isolation structure 120 comprises one or more partial isolation structure segments 120p.

FIG. 5 illustrates a top-view 500 of some additional embodiments of an image sensor IC comprising a disclosed etch block structure.

As shown in top-view 500, a back-side isolation structure 120 wraps around respective ones of a plurality of pixel regions 104 in a closed loop, so as to separate neighboring ones of the plurality of pixel regions 104 from one another. The back-side isolation structure 120 comprises a grid layout that extends in a first direction 216 and in a second direction 218 that is perpendicular to the first direction 216, as viewed in the top-view 500.

The etch block structure 116 is arranged below cross-roads between segments of the back-side isolation structure 120 extending in the first direction 216 and the second direction 218. The etch block structure 116 has a cross-shape as viewed in the top-view 500. The cross-shape of the etch block structure 116 has outermost sidewalls that are separated by an angle 502 that is approximately equal to 90°, as measured along a space that is outside of the etch block structure 116. By having the etch block structure 116 with a cross-shape, the etch block structure 116 is able to better control over-etching at cross-roads between perpendicular segments of the back-side isolation structure 120.

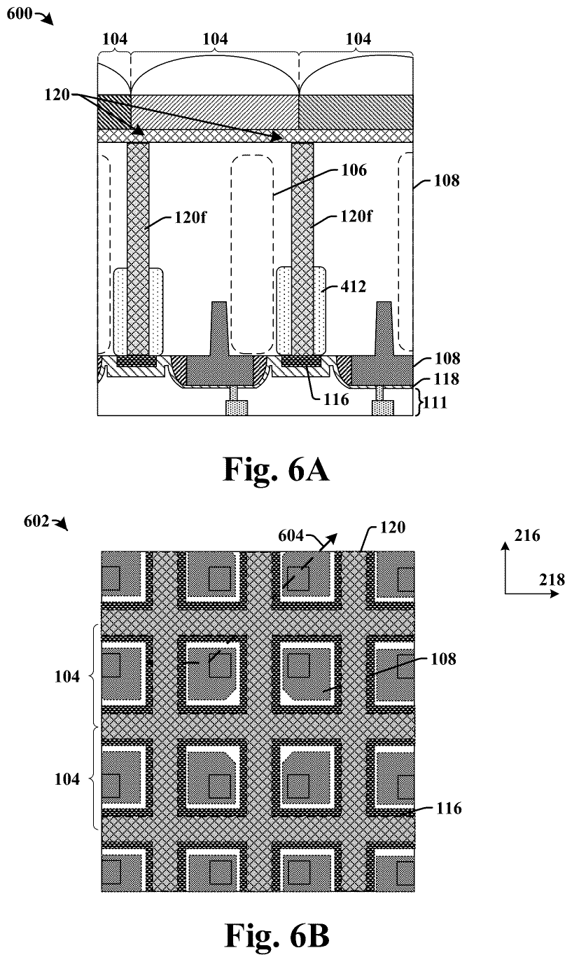

FIG. 6A illustrates a cross-sectional view of some additional embodiments of an image sensor IC 600 comprising a disclosed etch block structure.

The image sensor IC 600 includes a substrate 102 having a plurality of pixel regions 104 respectively comprising one of a plurality of gate structures 108. An etch block structure 116 is disposed on the substrate 102 between the plurality of gate structures 108. A back-side isolation structure 120 extends through the substrate 102 along opposing sides of the plurality of pixel regions 104. The back-side isolation structure 120 comprises one or more full isolation structure segments 120f on opposing sides of the plurality of pixel regions 104. In some embodiments, the one or more full isolation structure segments 120f may extend through a doped isolation region 412 to improve electrical isolation between neighboring ones of the plurality of pixel regions 104.

FIG. 6B illustrates a top-view 602 of some additional embodiments of the image sensor IC 600 of FIG. 6A. FIG. 6A is taken along cross-sectional line 604 of top-view 602. As shown in top-view 602, the back-side isolation structure 120 continuously extends in a closed loop around a plurality of pixel regions 104. The etch block structure 116 also continuously extends in a closed loop around a plurality of pixel regions 104 above the back-side isolation structure 120. Because the etch block structure 116 continuously extends in a closed loop around a plurality of pixel regions 104 above the back-side isolation structure 120, the back-side isolation structure 120 is able to include full isolation structure segments 120f that completely extend through the substrate 102 in a closed loop surrounding the plurality of pixel regions 104. In some embodiments (not shown), each of the plurality of pixel regions 104 may comprise a separate floating diffusion region that is separated from an adjacent floating diffusion region by the full isolation structure segments 120f.

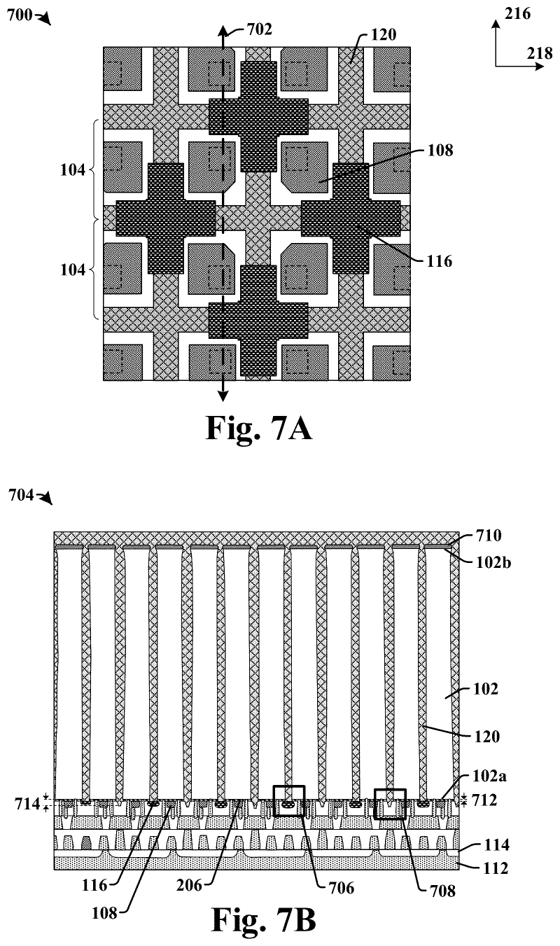

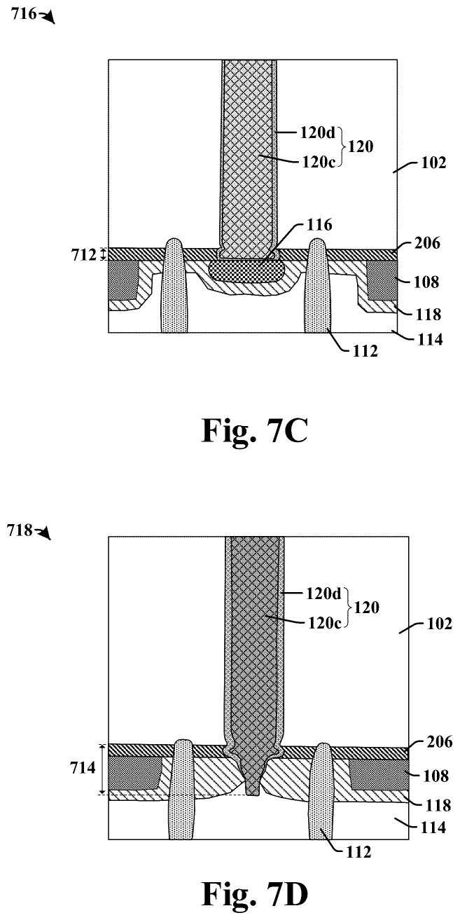

FIGS. 7A-7D illustrate some additional embodiments of an image sensor IC comprising a disclosed etch block structure.

FIG. 7A illustrates a top-view of some additional embodiments of the image sensor IC 700. The image sensor IC 700 includes a back-side isolation structure 120 that continuously extends in a closed loop around a plurality of pixel regions 104. An etch block structure 116 covers cross-roads between segments of the back-side isolation structure 120 extending in a first direction 216 and in a second direction 218. The etch block structure 116 includes a cross-shape.

FIG. 7B illustrates a cross-sectional view 704 taken along cross-sectional line 702 of the top-view of FIG. 7A. As shown in cross-sectional view 704, the back-side isolation structure 120 extends through a substrate 102, from a first side 102a of the substrate 102 to an opposing second side 102b of the substrate 102. In some embodiments, a dielectric mask 710 may be arranged along the second side 102b of the substrate 102 between segments of the back-side isolation structure 120.

The back-side isolation structure 120 comprises one or more full isolation structure segments that include parts that terminate in the etch block structure 116 and parts that do not terminate in the etch block structure 116. In some embodiments, the back-side isolation structure 120 may alternate between the parts that terminate in the etch block structure 116 and the parts that do not terminate in the etch block structure 116, as viewed in the cross-sectional view 704. The parts that terminate in the etch block structure 116 extend to a first depth 712 past the first side 102a of the substrate 102 and have a first flat lower surface facing the etch block structure 116 (as shown in section 706). The parts that do not terminate in the etch block structure 116 extend to a second depth 714 past the first side 102a of the substrate 102 (as shown in section 708). In some embodiments, the second depth 714 is larger than the first depth 712.

FIG. 7C illustrates a cross-sectional view 716 of section 706 of FIG. 7B. As shown in cross-sectional view 716, the back-side isolation structure 120 extends from a first segment within a substrate 102 to a second segment within a first dielectric 206 that is between the substrate 102 and the etch block structure 116. In some embodiments, the back-side isolation structure 120 comprises a conductive core 120c and a dielectric liner 120d surrounding the conductive core 120c. The second segment comprises a bulbus shape that has a substantially flat lower surface that faces the etch block structure 116. In some embodiments, the substantially flat lower surface may have a larger width than one or more overlying parts of the back-side isolation structure 120. The bulbus shape has an asymmetric curvature along a laterally bisecting line, which gives the bulbus shape a maximum width along a lower half of the bulbus shape. The first segment has a first width and the second segment has a second width. The first width and the second width are different from one another. In some embodiments, the second width may be larger than the first width.

FIG. 7D illustrates a cross-sectional view 718 of section 708 of FIG. 7B. As shown in cross-sectional view 718, the back-side isolation structure 120 extends from a first segment within the substrate 102, to a second segment within a first dielectric 206, and to a third segment that is within a CESL 118 and that protrudes through the CESL 118. The second segment comprises a bulbus shape that has a maximum width that is near a vertical center of the bulbus segment. In some embodiments, the third segment has tapered sides that slope inward towards a bottom of the back-side isolation structure 120. In some embodiments, the tapered sides that are coupled to a substantially flat lower surface having a smaller width than one or more overlying parts of the back-side isolation structure 120. The first segment has a first width, the second segment has a second width and the third segment has a third width. The first width, the second width, and the third width are different from one another. In some embodiments, the second width is larger than the first width and the first width is larger than the third width.

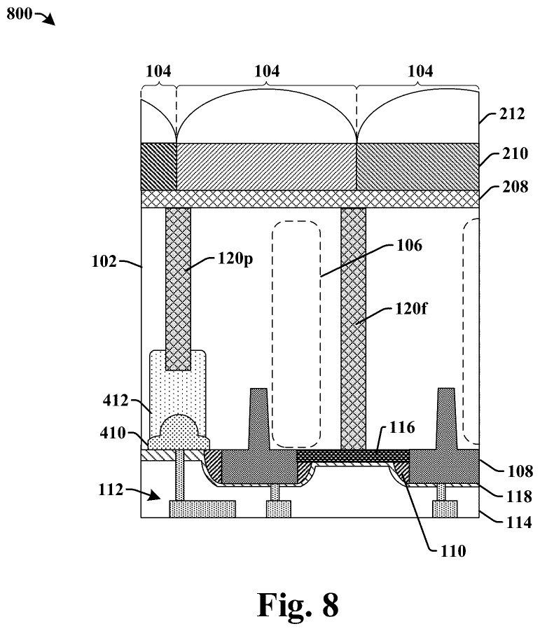

FIG. 8 illustrates some additional embodiments of an image sensor IC 800 comprising a disclosed etch block structure.

The image sensor IC 800 comprises an etch block structure 116 that continuously extends between outermost sidewalls of neighboring ones of the plurality of gate structures 108. One or more sidewall spacers 110 are arranged along opposing sides of the plurality of gate structures 108. The one or more sidewall spacers 110 rest on an upper surface of the etch block structure 116 facing away from the substrate 102. A back-side isolation structure 120 extends through the substrate 102 to contact a lower surface of the etch block structure 116 facing the substrate 102. By having the etch block structure 116 continuously extend between outermost sidewalls of neighboring ones of the plurality of gate structures 108, over-etching errors due to misalignment can be mitigated thereby improving electrical isolation between neighboring ones of the plurality of pixel regions 104.

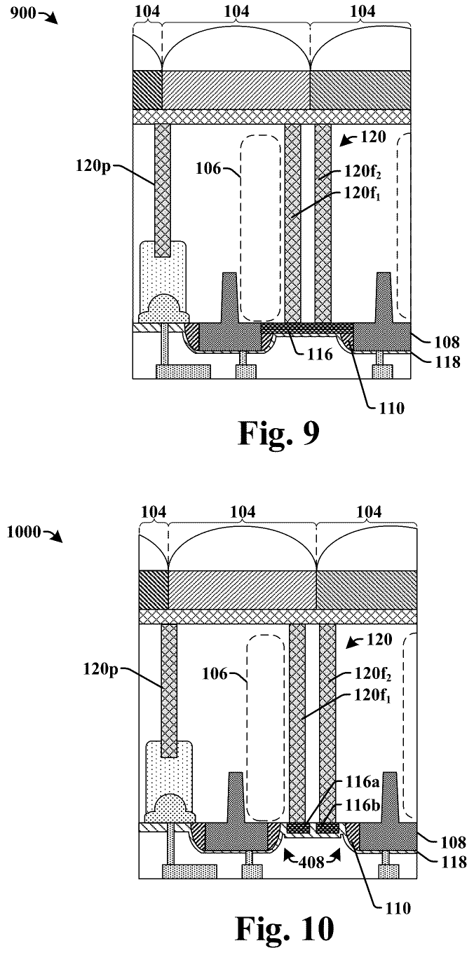

FIG. 9 illustrates some additional embodiments of an image sensor IC 900 comprising a disclosed etch block structure.

The image sensor IC 900 comprises an etch block structure 116 continuously extending between outermost sidewalls of neighboring ones of a plurality of gate structures 108 on a substrate 102. One or more sidewall spacers 110 are arranged along opposing sides of the plurality of gate structures 108. The one or more sidewall spacers 110 rest on an upper surface of the etch block structure 116 facing away from the substrate 102.

A back-side isolation structure 120 is disposed within the substrate 102. The back-side isolation structure 120 comprises one or more partial isolation structure segments 120p arranged along a first side of one of the plurality of pixel regions 104 and two full isolation structure segments 120f1-120f2 arranged along a second side of the one of the plurality of pixel regions 104. The two full isolation structure segments 120f1-120f2 comprise a first full isolation structure segment 120f1 laterally separated from a second full isolation structure segment 120f2 by the substrate 102. Both the first full isolation structure segment 120f1 and the second full isolation structure segment 120f2 extend from a second side 102b of the substrate 102 to the etch block structure 116. The etch block structure 116 laterally and continuously extends past opposing sides of the first full isolation structure segment 120f1 and the second full isolation structure segment 120f2. By having two full isolation structure segments 120f1-120f2 disposed between neighboring ones of the plurality of pixel regions 104, electrical isolation between the neighboring ones of the plurality of pixel regions 104 can be improved.

FIG. 10 illustrates some additional embodiments of an image sensor IC 1000 comprising a disclosed etch block structure

The image sensor IC 1000 comprises a first etch block structure 116a and a second etch block structure 116b laterally between outermost sidewalls of neighboring ones of a plurality of gate structures 108 on a substrate 102. The first etch block structure 116a is laterally separated from the second etch block structure 116b by a non-zero distance. In some embodiments, a CESL 118 is disposed laterally between the first etch block structure 116a and the second etch block structure 116b.

A back-side isolation structure 120 is disposed within the substrate 102. The back-side isolation structure 120 comprises one or more partial isolation structure segments 120p arranged along a first side of one of the plurality of pixel regions 104 and two full isolation structure segments 120f1-120f2 arranged along a second side of the one of the plurality of pixel regions 104. The two full isolation structure segments 120f1-120f2 comprise a first full isolation structure segment 120f1 laterally separated from a second full isolation structure segment 120f2 by the substrate 102. The first full isolation structure segment 120f1 extends from a second side 102b of the substrate to the first etch block structure 116a and the second full isolation structure segment 120f2 extends from the second side 102b of the substrate to the second etch block structure 116b.

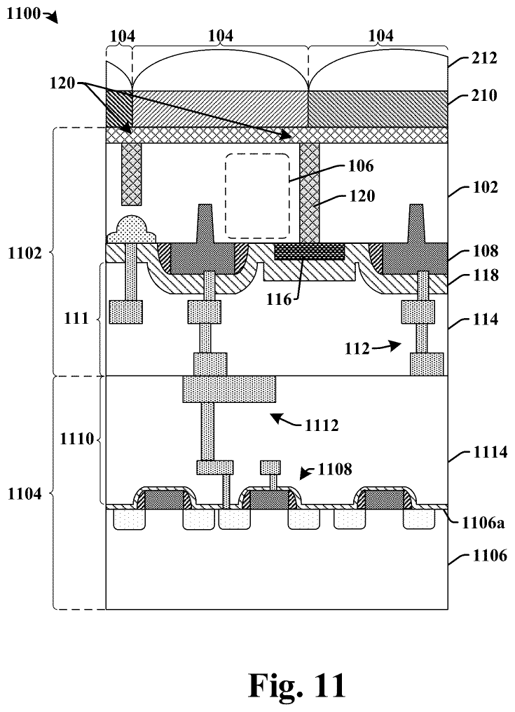

FIG. 11 illustrates some embodiments of a multi-dimensional integrated chip structure 1100 comprising an image sensor IC including a disclosed etch block structure.

The multi-dimensional integrated chip structure 1100 comprises a first integrated chip tier 1102 (e.g., a first die) and a second integrated chip tier 1104 (e.g., a second die) stacked onto one another. In some embodiments, the first integrated chip tier 1102 may be bonded to the second integrated chip tier 1104 in a face-to-face bonding configuration, while in other embodiments (not shown) the first integrated chip tier 1102 may be bonded to the second integrated chip tier 1104 in a face-to-back or a back-to back bonding configuration. In some additional embodiments (not shown), the integrated chip structure may comprise one or more additional tiers.

The first integrated chip tier 1102 comprises a substrate 102 including a plurality of pixels regions 104 respectively comprising one of a plurality of image sensing elements 106 and one of a plurality of gate structures 108. The plurality of pixel regions 104 are separated from one another by a back-side isolation structure 120 that terminates into an etch block structure 116 disposed along a front-side of the substrate 102. The first integrated chip tier 1102 further comprises an interconnect structure 111 disposed on the substrate 102. The interconnect structure 111 includes a plurality of conductive interconnects 112 arranged within an ILD structure 114.

The second integrated chip tier 1104 comprises a plurality of logic devices 1108 disposed on and/or within a front-side 1106a of a second substrate 1106. In various embodiments, the plurality of logic devices 1108 may comprise a planar FET, a FinFET, a gate all around FET (e.g., a nanosheet), and/or the like. In some embodiments, the one or more logic devices 1108 may be configured to perform operations such as image processing, analog data processing (e.g., noise reduction, data sampling, etc.), or the like. A second interconnect structure 1110 is disposed on the front-side 1106a of the second substrate 1106. The second interconnect structure 1110 comprises a second plurality of interconnects 1112 disposed within a second inter-level dielectric (ILD) structure 1114. The second plurality of interconnects 1112 are electrically coupled to the plurality of logic devices 1108. The interconnect structure 111 is bonded to the second interconnect structure 1110 along a bonding interface comprising one or more conductive interfaces and one or more dielectric interfaces.

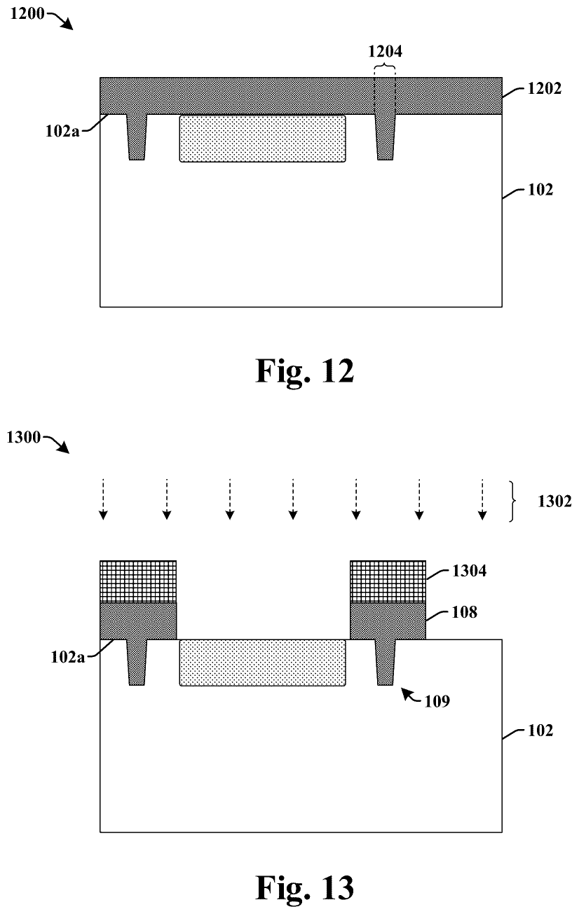

FIGS. 12-29 illustrate cross-sectional views 1200-2900 of some embodiments of a method of forming an image sensor IC comprising a disclosed etch block structure. Although the cross-sectional views 1200-2900 shown in FIGS. 12-29 are described with reference to a method of forming an image sensor integrated chip comprising an etch block structure, it will be appreciated that the structures shown in FIGS. 12-29 are not limited to the method of formation but rather may stand alone separate of the method.

As shown in cross-sectional view 1200 of FIG. 12, one or more gate layers 1202 are formed along a first side 102a of a substrate 102. The one or more gate layer 1202 may comprise a gate dielectric layer and a gate electrode layer formed onto the gate dielectric layer. In various embodiments, the gate dielectric layer may be formed by a deposition process and/or a thermal process. In some embodiments, the gate electrode may be formed by a deposition technique (e.g., physical vapor deposition (PVD), chemical vapor deposition (CVD), plasma enhanced CVD (PE-CVD), atomic layer deposition (ALD), etc.). In some embodiments, the substrate 102 may be etched prior to forming the one or more gate layers to form one or more recesses 1204 extending into the substrate 102. In such embodiments, the one or more gate layers 1202 extend into the one or more recesses 1204.

As shown in cross-sectional view 1300 of FIG. 13, the one or more gate layers (e.g., 1202 of FIG. 12) are patterned to form a plurality of gate structures 108. In various embodiments, the plurality of gate structures 108 may correspond to a transfer transistor, a source-follower transistor, a row select transistor, and/or a reset transistor. In some embodiments, the plurality of gate structures 108 may comprise a vertical transfer gate comprising a protrusion 109 extending outward from a lower surface of the vertical transfer gate to within the substrate 102. In some embodiments, the one or more gate layers may be patterned according to one or more patterning processes. The one or more patterning processes may be performed by using a photolithography process to form a first mask 1304 (e.g., a photosensitive material, a hard mask, or the like) over the one or more gate layers and subsequently exposing the one or more gate layers to one or more etchants 1302 according to the first mask 1304.

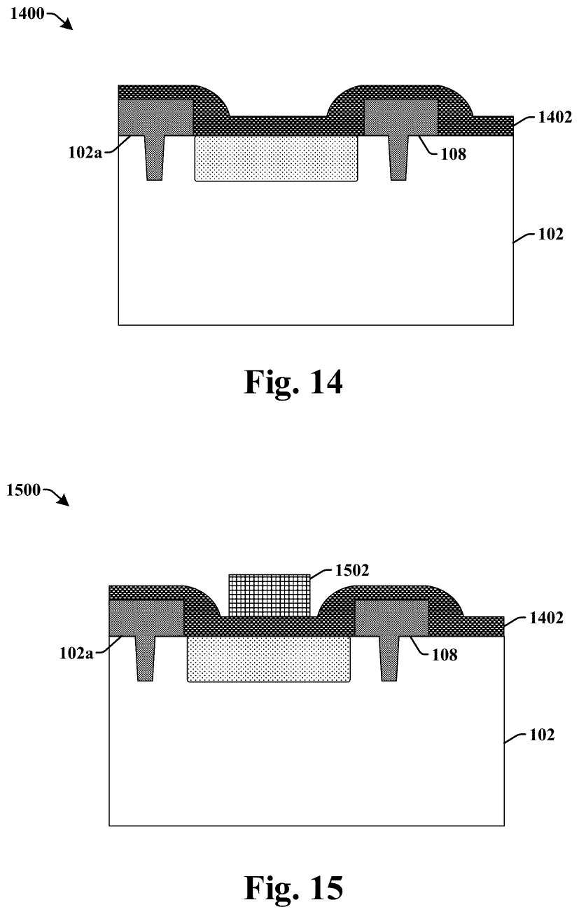

As shown in cross-sectional view 1400 of FIG. 14, an etch block layer 1402 is formed onto the first side 102a of the substrate 102 and onto the plurality of gate structures 108. The etch block layer 1402 conformally covers sidewalls and an upper surface of the plurality of gate structures 108. The etch block layer 1402 may be formed by a deposition technique (e.g., PVD. CVD, PE-CVD, ALD, etc.) In various embodiments, the etch block layer 1402 may comprise a nitride-based dielectric (e.g., silicon nitride, silicon oxynitride, or the like), a carbide-based layer (e.g., silicon carbide, silicon oxycarbide), a titanium nitride-based layer, an aluminum-based layer, or the like

As shown in cross-sectional view 1500 of FIG. 15, a second mask 1502 is formed onto the etch block layer 1402. The second mask 1502 may be formed laterally between the plurality of gate structures 108. In some embodiments, the second mask 1502 (e.g., a photosensitive material, a hard mask, or the like) may be formed over the etch block layer 1402 using a photolithography process.

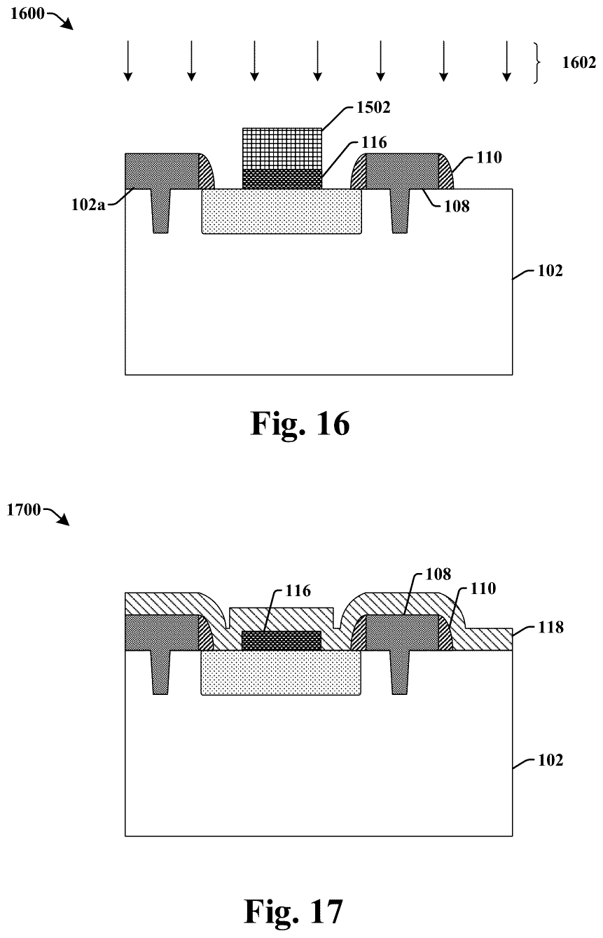

As shown in cross-sectional view 1600 of FIG. 16, the etch block layer (e.g., 1402 of FIG. 14) is patterned to form an etch block structure 116 laterally between the plurality of gate structures 108. In some embodiments, the etch block layer may be patterned by exposing the etch block layer to one or more etchants 1602 according to the second mask 1502. In some embodiments, one or more sidewall spacers 110 may be formed along opposing sides of the plurality of gate structures 108. In some embodiments, the one or more sidewall spacers 110 may be formed by etching the etch blocking layer. In other embodiments, the one or more sidewall spacers 110 may be formed by a separate deposition and etching process. In such embodiments, the one or more sidewall spacers 110 may be formed by depositing a spacer layer (e.g., a nitride, an oxide, etc.) onto the first side 102a of the substrate 102 and selectively etching the spacer layer to form the one or more sidewall spacers 110.

As shown in cross-sectional view 1700 of FIG. 17, a contact etch stop layer (CESL) 118 is formed onto the plurality of gate structures 108 and the etch block structure 116. In some embodiments, the CESL 118 may be formed laterally and directly between an outermost sidewall of the etch block structure 116 and an outermost sidewall of a closest neighboring one of the plurality of gate structures 108. The CESL 118 may be formed by a deposition technique (e.g., PVD, CVD, PE-CVD, ALD, etc.). In various embodiments, the CESL 118 may comprise a nitride (e.g., silicon nitride, silicon oxynitride, etc.), a carbide (e.g., silicon carbide, silicon oxycarbide), or the like. In some embodiments, the CESL 118 may be conformally formed so that one or more pits 408 are formed laterally between the etch block structure 116 and neighboring ones of the plurality of gate structures 108.

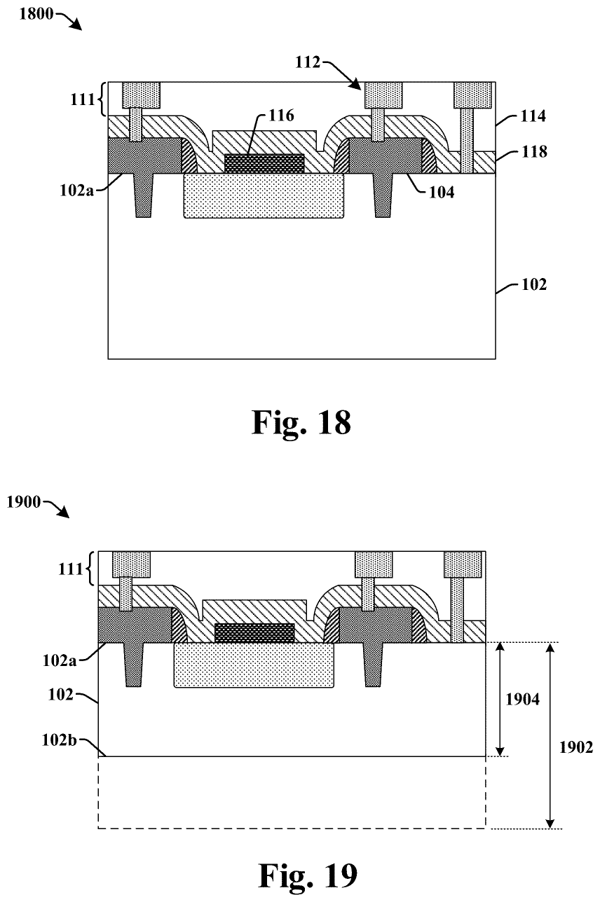

As shown in cross-sectional view 1800 of FIG. 18, an interconnect structure 111 is formed along the first side 102a of the substrate 102. The interconnect structure 111 may be formed by forming a plurality of conductive interconnects 112 within an inter-level dielectric (ILD) structure 114. The ILD structure 114 comprises a plurality of stacked ILD layers, while the plurality of conductive interconnects 112 comprise alternating layers of conductive wires and vias. In some embodiments, one or more of the plurality of conductive interconnects 112 may be formed using a damascene process (e.g., a single damascene process or a dual damascene process). The damascene process may be performed by forming an ILD layer over the first side 102a of the substrate 102, etching the ILD layer to form a via hole and/or a trench, and filling the via hole and/or trench with a conductive material. In some embodiments, the ILD layer may be deposited by a physical vapor deposition technique (e.g., PVD, CVD, PE-CVD, ALD, etc.) and the conductive material may be formed using a deposition process and/or a plating process (e.g., electroplating, electro-less plating, etc.). In various embodiments, the conductive material may comprise tungsten, copper, aluminum, copper, or the like.

As shown in cross-sectional view 1900 of FIG. 19, the substrate 102 may be thinned. Thinning the substrate 102 reduces a thickness of the substrate 102 from a first thickness 1902 to a second thickness 1904 that is less than the first thickness 1902. Thinning the substrate 102 allows for radiation to pass more easily to an image sensing element (e.g., subsequently formed). In various embodiments, the substrate 102 may be thinned by etching and/or mechanical grinding a second side 102b of the substrate 102. In some embodiments, the interconnect structure 111 may be bonded to a support substrate (e.g., a silicon substrate) prior to thinning to give the substrate 102 mechanical support during the thinning process.

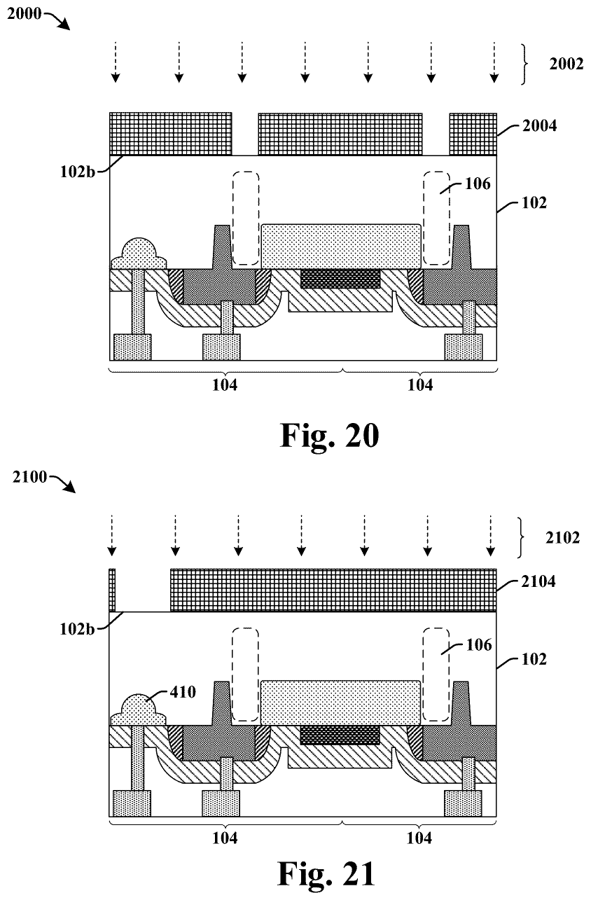

As shown in cross-sectional view 2000 of FIG. 20, image sensing elements 106 are formed within a plurality of pixel regions 104 within the substrate 102. In some embodiments, the image sensing elements 106 may comprise photodiodes formed by implanting one or more dopant species into the second side 102b of the substrate 102. For example, the image sensing elements 106 may be formed by selectively performing a first implantation process 2002 to form a first region having a first doping type (e.g., n-type), and subsequently performing a second implantation process to form a second region abutting the first region and having a second doping type (e.g., p-type) different than the first doping type. In some embodiments, the first implantation process 2002 may be performed according to a third mask 2004 formed by a photolithography process.

As shown in cross-sectional view 2100 of FIG. 21, a floating diffusion region 410 is formed within the substrate 102. In some embodiments, the floating diffusion region 410 may be formed using one of the first or second implantation processes of FIG. 20. In other embodiments, the floating diffusion region 410 may be formed according to a third implantation process 2102 performed according to a fourth mask 2104 formed by a photolithography process.

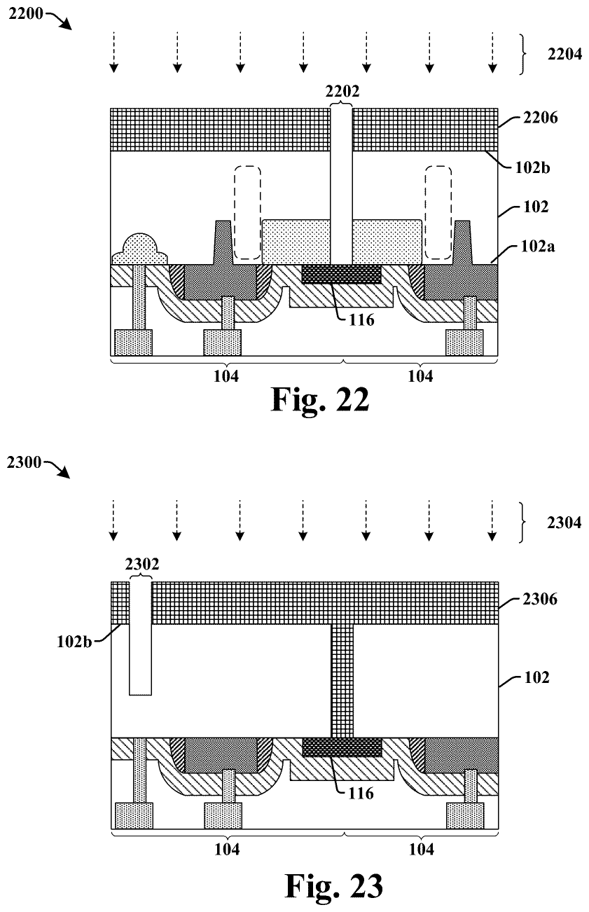

As shown in cross-sectional view 2200 of FIG. 22, one or more trenches 2202 are formed within the substrate 102 along one or more sides of the plurality of pixel regions 104. The one or more trenches 2202 vertically extend from the second side 102b (e.g., the back-side) of the substrate 102 to the etch block structure 116 arranged along the first side 102a of the substrate 102. In some embodiments, the one or more trenches 2202 may be formed by selectively etching the second side 102b of the substrate 102 with a first etching process. In some embodiments, the second side 102b of the substrate 102 may be selectively etched by exposing the second side 102b of the substrate 102 to one or more etchants 2204 according to a fifth mask 2206. In some embodiments, the fifth mask 2206 may comprise a photoresist, a hard mask, or the like. In some embodiments, the one or more etchants 2204 may comprise a dry etchant. In some embodiments, the dry etchant may have an etching chemistry comprising one or more of oxygen (O₂), nitrogen (N₂), hydrogen (H₂), argon (Ar), and/or a fluorine species (e.g., CF₄, CHF₃, C₄F₈, etc.).

Because the etch block structure 116 is disposed on the first side 102a of the substrate 102, over-etching of the first etching process can be controlled while mitigating damage to the plurality of pixel regions 104 (e.g., relative to damage that may be caused by forming an STI structure within the substrate 102). Furthermore, the formation of the etch block structure 116 can be formed at a lower cost than other etch blocking options (e.g., an STI structure) and the use of the etch block structure 116 to control the first etching process allows for an isolation structure to be formed without changes to the process and/or design rules used to form the image sensor IC.

As shown in cross-sectional view 2300 of FIG. 23, in some additional embodiments, the one or more additional trenches 2302 may be formed by selectively etching the second side 102b of the substrate 102 with a second etching process. In some embodiments, the second side 102b of the substrate 102 may be selectively etched by exposing the second side 102b of the substrate 102 to one or more etchants 2304 according to a sixth mask 2306. The one or more additional trenches 2302 may extend into the substrate 102 to a lesser depth than the one or more trenches 2202.

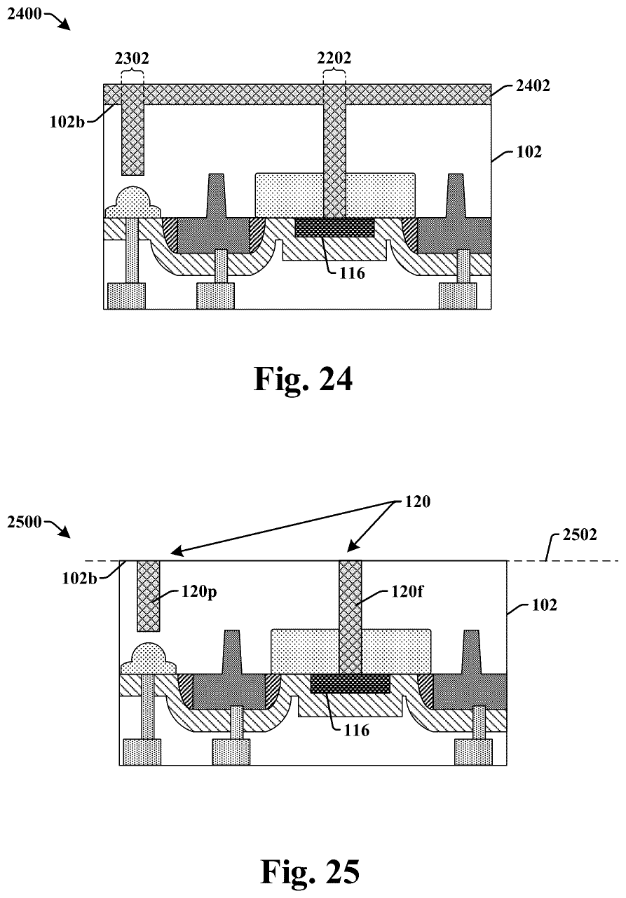

As shown in cross-sectional view 2400 of FIG. 24, one or more dielectric materials 2402 are formed within the one or more trenches 2202 and/or the one or more additional trenches 2302. In some embodiments, the one or more dielectric materials 2402 may be formed to line interior surfaces of the substrate 102 forming the one or more trenches 2202 and/or the one or more additional trenches 2302 and to further cover the second side 102b of the substrate 102. In some embodiments, the one or more dielectric materials 2402 may be formed by way of a vapor deposition process (e.g., a chemical vapor deposition (CVD) process, a plasma enhanced CVD process, or the like). In other embodiments, the one or more dielectric materials 2402 may be formed by way of an atomic layer deposition (ALD) process. The ALD process can improve fill of the one or more trenches 2202 and/or the one or more additional trenches 2302, which may be otherwise difficult to fill due to a relatively large depth and small width (e.g., a width of between approximately 10% and approximately 20% of a width of the pixel region 104).

As shown in cross-sectional view 2500 of FIG. 25, after forming the one or more dielectric materials (e.g., 2402 of FIG. 24), a planarization process (e.g., a chemical mechanical planarization (CMP) process) may be performed along line 2502 to remove the one or more dielectric materials from the second side 102b of the substrate 102 and form a back-side isolation structure 120 within the substrate 102. In some embodiments, the back-side isolation structure 120 may comprise one or more full isolation structure segments 120f and one or more partial isolation structure segments 120p arranged on opposing sides of the plurality of pixel regions 104. In other embodiments (not shown), the back-side isolation structure 120 may comprise one or more full isolation structure segments 120f continuously surrounding the plurality of pixel regions 104 in a closed and unbroken loop.

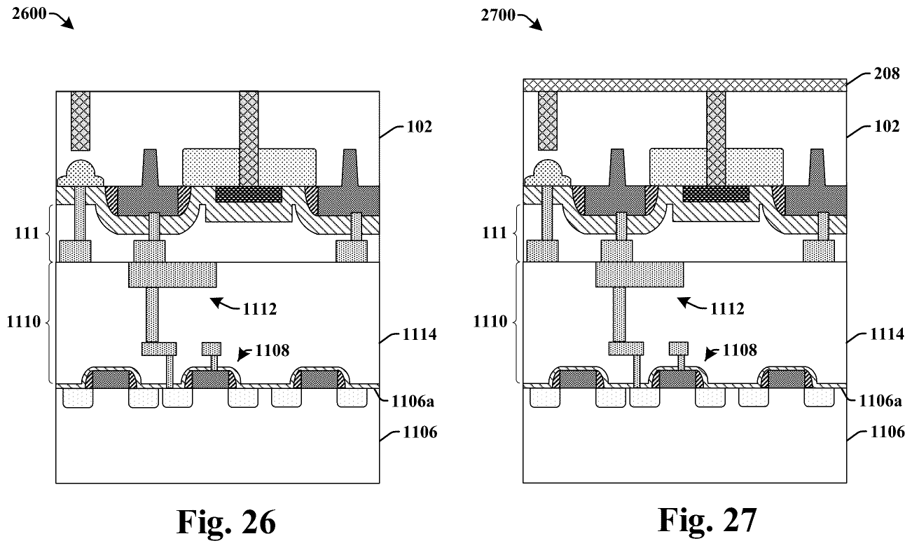

As shown in cross-sectional view 2600 of FIG. 26, the substrate 102 is bonded to a second substrate 1106 by way of a second interconnect structure 1110 disposed onto the second substrate 1106. In some embodiments, the second substrate 1106 may be bonded to the substrate 102 so that the interconnect structure 111 and the second interconnect structure 1110 are between the substrate 102 and the second substrate 1106. In some embodiments, the second substrate 1106 may be bonded to the substrate 102 by way of a hybrid bonding process that forms a hybrid bonding interface comprising a dielectric interface and a metal interface. In some embodiments, the support substrate may be removed (e.g., by way of an etching process and/or a grinding process and/or CMP process) after bonding the substrate 102 to the second substrate 1106.

As shown in cross-sectional view 2700 of FIG. 27, a dielectric planarization layer 208 is formed on the second side 102b of the substrate 102. In various embodiments, the dielectric planarization layer 208 may comprise an oxide, a nitride, a carbide, or the like. In some embodiments, the dielectric planarization layer 208 may be formed by a deposition technique (e.g., PVD, CVD, PE-CVD, ALD, etc.).

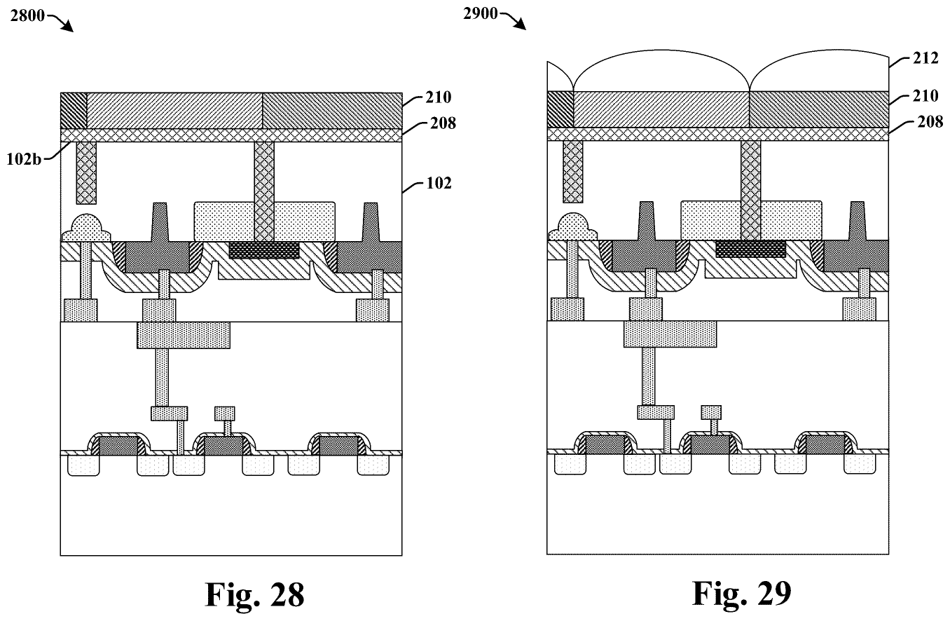

As shown in cross-sectional view 2800 of FIG. 28, a plurality of color filters 210 are formed on the second side 102b of the substrate 102. In some embodiments, the plurality of color filters 210 are formed by depositing (e.g., via CVD, PVD, ALD, sputtering, a spin-on process, etc.) a light filtering material(s) onto the substrate 102. The light filtering material(s) is a material that allows for the transmission of radiation (e.g., light) having a specific wavelength range, while blocking light of wavelengths outside of the specified range. Subsequently, in some embodiments, a planarization process (e.g., CMP) may be performed on the plurality of color filters 210 to planarize the upper surfaces of the plurality of color filters 210.

As shown in cross-sectional view 2900 of FIG. 29, a plurality of micro-lenses 212 are formed over the plurality of color filters 210. In some embodiments, the plurality of micro-lenses 212 may be formed by depositing a micro-lens material on the plurality of color filters 210 (e.g., via CVD, PVD, ALD, sputtering, a spin-on process, etc.). A micro-lens template (not shown) having a curved upper surface is patterned above the micro-lens material. In some embodiments, the micro-lens template may comprise a photoresist material exposed using a distributing exposing light dose (e.g., for a negative photoresist more light is exposed at a bottom of the curvature and less light is exposed at a top of the curvature), developed, and baked to form a rounding shape. The plurality of micro-lenses 212 are then formed by selectively etching the micro-lens material according to the micro-lens template.

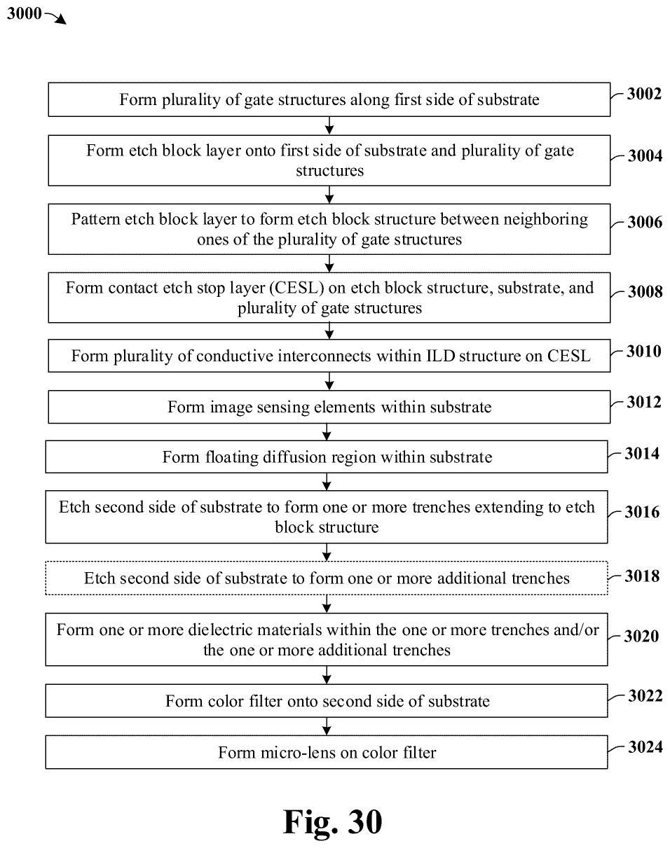

FIG. 30 illustrates a flow diagram of some embodiments of a method 3000 of forming an image sensor IC comprising a disclosed etch block structure.

While method 3000 is illustrated and described herein as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At act 3002, a plurality of gate structures are formed along a first side of a substrate. FIGS. 12-13 illustrate cross-sectional views, 1200-1300, of some embodiments corresponding to act 3002.

At act 3004, an etch blocking layer is formed onto the first side of the substrate and the plurality of gate structures. FIG. 14 illustrates a cross-sectional view 1400 of some embodiments corresponding to act 3004.

At act 3006, the etch blocking layer is patterned to form an etch block structure between neighboring ones of the plurality of gate structures. FIGS. 15-16 illustrate cross-sectional views 1500-1600 of some embodiments corresponding to act 3006.

At act 3008, a contact etch stop layer (CESL) is formed on the etch block structure, the substrate, and the plurality of gate structures. FIG. 17 illustrates a cross-sectional view 1700 of some embodiments corresponding to act 3008.

At act 3010, a plurality of conductive interconnects are formed within an inter-level dielectric (ILD) structure formed on the CESL. FIG. 18 illustrates a cross-sectional view 1800 of some embodiments corresponding to act 3010.

At act 3012, image sensing elements are formed within the substrate. FIG. 20 illustrates a cross-sectional view 2000 of some embodiments corresponding to act 3012.

At act 3014, a floating diffusion region is formed within the substrate. FIG. 21 illustrates a cross-sectional view 2100 of some embodiments corresponding to act 3014.

At act 3016, a second side of the substrate is etched to form one or more trenches extending to the etch block structure. FIG. 22 illustrates a cross-sectional view 2200 of some embodiments corresponding to act 3016.

At act 3018, a second side of the substrate is etched to form one or more additional trenches, in some embodiments. FIG. 23 illustrates a cross-sectional view 2300 of some embodiments corresponding to act 3018.

At act 3020, one or more dielectric materials are formed within the one or more trenches and/or the one or more additional trenches. FIGS. 24-25 illustrate cross-sectional views 2400-2500 of some embodiments corresponding to act 3020.

At act 3022, a color filter is formed between sidewalls of the grid structure and/or the dielectric material. FIG. 28 illustrates a cross-sectional view 2800 of some embodiments corresponding to act 3022.

At act 3024, a micro-lens is formed on the color filter. FIG. 29 illustrates a cross-sectional view 2900 of some embodiments corresponding to act 3024.

Accordingly, in some embodiments, the present disclosure relates to an image sensor integrated chip having an etch block structure configured to mitigate damage due to over-etching during formation of a back-side isolation structure (e.g., a back-side deep trench isolation (BDTI) structure).

In some embodiments, the present disclosure relates to an image sensor integrated chip. The image sensor integrated chip includes a plurality of gate structures arranged along a first side of a substrate within a plurality of pixel regions; an etch block structure arranged on the first side of the substrate between neighboring ones of the plurality of gate structures; a contact etch stop layer (CESL) arranged on the etch block structure between the neighboring ones of the plurality of gate structures; and an isolation structure disposed between one or more sidewalls of the substrate and extending from a second side of the substrate to the first side of the substrate, the etch block structure being vertically between the isolation structure and the CESL. In some embodiments, the isolation structure contacts the etch block structure. In some embodiments, the etch block structure includes outermost sidewalls between the neighboring ones of the plurality of gate structures. In some embodiments, the etch block structure has a smaller thickness at a lateral center of the etch block structure than between the lateral center and an outermost sidewall of the etch block structure. In some embodiments, the etch block structure is separated from the substrate by a dielectric, a part of the isolation structure being laterally surrounded by the dielectric. In some embodiments, a side of the isolation structure includes a divot along an interface between the substrate and the dielectric. In some embodiments, the isolation structure has a first width between the one or more sidewalls of the substrate and a second width between one or more sidewalls of the dielectric, the first width being different than the second width. In some embodiments, the image sensor integrated chip further includes a second etch block structure arranged between the neighboring ones of the plurality of gate structures, the etch block structure being separated from the second etch block structure by the CESL; and a second isolation structure disposed between one or more additional sidewalls of the substrate and extending from the second side of the substrate to the first side of the substrate, the second etch block structure being vertically between the second isolation structure and the CESL. In some embodiments, the image sensor integrated chip further includes a second isolation structure disposed between one or more additional sidewalls of the substrate and extending from the second side of the substrate to the first side of the substrate, the etch block structure being vertically between the second isolation structure and the CESL. In some embodiments, the etch block structure is arranged below cross-roads of segments of the isolation structure extending in different directions as viewed in a top-view of the isolation structure.

In other embodiments, the present disclosure relates to an image sensor integrated chip. The image sensor integrated chip includes an isolation structure disposed within a substrate and at least laterally wrapping around a pixel region, the isolation structure extending from a first side of the substrate to a second side of the substrate; an etch block structure arranged on the first side of the substrate, the isolation structure contacting the etch block structure; a contact etch stop layer (CESL) arranged on the etch block structure; an inter-level dielectric (ILD) layer arranged on the CESL; and one or more conductive interconnects disposed within the ILD layer and extending through the CESL. In some embodiments, the isolation structure includes a first segment extending in a first direction and a second segment extending in a second direction that is perpendicular to the first direction, as viewed in a top-view of the isolation structure; and the etch block structure is arranged on the first side of the substrate below an intersection of the first segment and the second segment. In some embodiments, the image sensor integrated chip further includes a photodiode arranged within the substrate in the pixel region, the isolation structure surrounding the photodiode; a floating diffusion region arranged along the first side of the substrate; and a gate structure arranged along the first side of the substrate, the gate structure being configured to control a movement of charge carriers from the photodiode to the floating diffusion region. In some embodiments, the image sensor integrated chip further includes one or more sidewall spacers arranged along opposing sides of the gate structure, the one or more sidewall spacers being laterally separated from the etch block structure by the CESL. In some embodiments, the image sensor integrated chip further includes one or more sidewall spacers arranged along opposing sides of the gate structure, the one or more sidewall spacers resting on an upper surface of the etch block structure facing away from the substrate.

In yet other embodiments, the present disclosure relates to a method of forming image sensor integrated chip. The method includes forming an etch block layer along a front-side of a substrate; patterning the etch block layer to form an etch block structure on the front-side of the substrate; forming a contact etch stop layer (CESL) on the etch block structure; forming one or more interconnects within an inter-level dielectric (ILD) structure formed on the CESL; etching a back-side of the substrate to form a trench extending to the etch block structure; and filling the trench with one or more dielectric materials. In some embodiments, the etch block structure is disposed laterally between a first pixel region and a second pixel region of the substrate. In some embodiments, the method further includes forming one or more conductive contacts to extend through the CESL to below a top of the etch block structure facing away from the substrate. In some embodiments, the method further includes forming a plurality of gate structures along the front-side of the substrate, the etch block structure being arranged directly between sidewalls of the plurality of gate structures. In some embodiments, the method further includes forming the CESL along sidewalls of the etch block structure and along a top surface of the etch block structure that faces away from the substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An image sensor integrated chip, comprising:
a plurality of gate structures arranged along a first side of a substrate within a plurality of pixel regions;
an etch block structure arranged on the first side of the substrate between neighboring ones of the plurality of gate structures;
a contact etch stop layer (CESL) arranged on the etch block structure between the neighboring ones of the plurality of gate structures; and
an isolation structure disposed between one or more sidewalls of the substrate and extending from a second side of the substrate to the first side of the substrate, wherein the etch block structure is vertically between the isolation structure and the CESL.

2. The image sensor integrated chip of claim 1, wherein the isolation structure contacts the etch block structure.

3. The image sensor integrated chip of claim 1, wherein the etch block structure comprises outermost sidewalls between the neighboring ones of the plurality of gate structures.

4. The image sensor integrated chip of claim 1, wherein the etch block structure has a smaller thickness at a lateral center of the etch block structure than between the lateral center and an outermost sidewall of the etch block structure.

5. The image sensor integrated chip of claim 1, wherein the etch block structure is separated from the substrate by a dielectric, a part of the isolation structure being laterally surrounded by the dielectric.

6. The image sensor integrated chip of claim 5, wherein a side of the isolation structure comprises a divot along an interface between the substrate and the dielectric.

7. The image sensor integrated chip of claim 5, wherein the isolation structure has a first width between the one or more sidewalls of the substrate and a second width between one or more sidewalls of the dielectric, the first width being different than the second width.

8. The image sensor integrated chip of claim 1, further comprising:
a second etch block structure arranged between the neighboring ones of the plurality of gate structures, wherein the etch block structure is separated from the second etch block structure by the CESL; and
a second isolation structure disposed between one or more additional sidewalls of the substrate and extending from the second side of the substrate to the first side of the substrate, wherein the second etch block structure is vertically between the second isolation structure and the CESL.

9. The image sensor integrated chip of claim 1, further comprising:
a second isolation structure disposed between one or more additional sidewalls of the substrate and extending from the second side of the substrate to the first side of the substrate, wherein the etch block structure is vertically between the second isolation structure and the CESL.

10. The image sensor integrated chip of claim 1, wherein the etch block structure is arranged below cross-roads of segments of the isolation structure extending in different directions as viewed in a top-view of the isolation structure.

11. An image sensor integrated chip, comprising:
an isolation structure disposed within a substrate and at least laterally wrapping around a pixel region, wherein the isolation structure extends from a first side of the substrate to a second side of the substrate;
an etch block structure arranged on the first side of the substrate, wherein the isolation structure contacts the etch block structure;
a contact etch stop layer (CESL) arranged on the etch block structure;
an inter-level dielectric (ILD) layer arranged on the CESL; and
one or more conductive interconnects disposed within the ILD layer and extending through the CESL.

12. The image sensor integrated chip of claim 11,
wherein the isolation structure comprises a first segment extending in a first direction and a second segment extending in a second direction that is perpendicular to the first direction, as viewed in a top-view of the isolation structure; and
wherein the etch block structure is arranged on the first side of the substrate below an intersection of the first segment and the second segment.

13. The image sensor integrated chip of claim 11, further comprising:
a photodiode arranged within the substrate in the pixel region, wherein the isolation structure surrounds the photodiode;
a floating diffusion region arranged along the first side of the substrate; and
a gate structure arranged along the first side of the substrate, wherein the gate structure is configured to control a movement of charge carriers from the photodiode to the floating diffusion region.

14. The image sensor integrated chip of claim 13, further comprising:
one or more sidewall spacers arranged along opposing sides of the gate structure, wherein the one or more sidewall spacers are laterally separated from the etch block structure by the CESL.

15. The image sensor integrated chip of claim 13, further comprising:
one or more sidewall spacers arranged along opposing sides of the gate structure, wherein the one or more sidewall spacers rest on an upper surface of the etch block structure facing away from the substrate.

16. A method of forming an image sensor integrated chip, comprising:
forming an etch block layer along a front-side of a substrate;
patterning the etch block layer to form an etch block structure on the front-side of the substrate;
forming a contact etch stop layer (CESL) on the etch block structure;
forming one or more interconnects within an inter-level dielectric (ILD) structure formed on the CESL;
etching a back-side of the substrate to form a trench extending to the etch block structure; and
filling the trench with one or more dielectric materials.

17. The method of claim 16, wherein the etch block structure is disposed laterally between a first pixel region and a second pixel region of the substrate.

18. The method of claim 16, further comprising:
forming one or more conductive contacts to extend through the CESL to below a top of the etch block structure facing away from the substrate.

19. The method of claim 16, further comprising:
forming a plurality of gate structures along the front-side of the substrate, wherein the etch block structure is arranged directly between sidewalls of the plurality of gate structures.

20. The method of claim 16, further comprising:
forming the CESL along sidewalls of the etch block structure and along a top surface of the etch block structure that faces away from the substrate.
